(19) United States
(12) Patent Application Publication
(10) Pub. No.: US 2010/0111650 A1
(43) Pub. Date: May 6, 2010

(54) AUTOMATIC SUBSTRATE LOADING STATION

(75) Inventors: DAVID H. QUACH, San Jose, CA (US); Tetsuya Ishikawa, Saratoga, CA (US)

Correspondence Address: PATTERSON & SHERIDAN, LLP - - APPM/TX, 3040 POST OAK BOULEVARD, SUITE 1500, HOUSTON, TX, 77056, US

(73) Assignee: APPLIED MATERIALS, INC., Santa Clara, CA (US)

(21) Appl. No.: 12/565,485

(22) Filed: Sep. 23, 2009

Related U.S. Application Data
(63) Continuation-in-part of application No. 12/023,572, filed on Jan. 31, 2008.

(51) Int. Cl. H01L 21/677

(52) U.S. Cl. 414/221; 414/222.01; 414/806

(57) ABSTRACT

Embodiments of the present invention provide method and apparatus for automatically loading substrates to a substrate carrier tray. On embodiment of the present invention provides an automatic substrate loader comprises a cassette handling mechanism, a substrate aligner configured to align a substrate, and a carrier tray aligner. The automatic substrate loader further comprises a first robot configured to transfer substrates between the substrate aligner and the substrate storage cassettes, and a second robot configured to transfer substrates between the substrate aligner and the carrier tray disposed on the carrier tray aligner.

### CROSS-REFERENCE TO RELATED APPLICATIONS

This application is continuation-in-part of the co-pending U.S. patent application Ser. No. 12/023,572 (Docket No. 11978), filed Jan. 31, 2008, which is herein incorporated by reference.

### BACKGROUND OF THE INVENTION

1. Field of the Invention

Embodiments of the present invention generally relate to the manufacture of semiconductor devices, such as light emitting diodes (LEDs). More particularly, embodiments of the present invention relate to method and apparatus for loading and unloading substrates to a substrate processing system.

2. Description of the Related Art

Semiconductor devices are generally formed on some kind of substrates, such as semiconductor substrates, glass substrates or sapphire substrates. During semiconductor manufacturing, substrates generally are loaded into a processing system, processed in the processing system, and unloaded from the processing system. The processing system may be a single chamber, or a cluster tool having one or more transfer chambers connected to two or more processing chambers.

During processing, substrates may be transferred substrate by substrate or batch by batch. For example, substrates used in manufacturing of light emitting diodes (LED), such as sapphire substrates, are usually transferred by batch. A plurality of substrates are disposed and transferred in a substrate carrier in a processing chamber or a cluster tool during processing. The substrate carrier may have a plurality of pockets, each pocket adapted to retain a substrate and allow a processing surface exposed to processing environment in a processing chamber.

Traditionally, sapphire substrates used in forming LED devices are manually loaded into a substrate carrier, then being transferred to a processing chamber or a processing system having multiple processing chambers. After processing, the substrates are manually unloaded from the substrate carrier. The processes are tedious and prone to human error.

Embodiments of the present invention provide method and apparatus of automatic loading and unloading substrates to a substrate carrier.

### SUMMARY OF THE INVENTION

Embodiments of the present invention generally relate to the manufacture of semiconductor devices, such as light emitting diodes (LEDs). More particularly, embodiments of the present invention relate to method and apparatus for loading and unloading substrates to a substrate processing system.

One embodiment of the present invention provides a substrate loading station comprising a cassette handling mechanism, wherein the cassette handling mechanism supports one or more substrate storage cassettes and moves each of the one or more substrate storage cassettes into and out of a loading position, a substrate aligner configured to align a substrate, a first robot configured to transfer substrates between the substrate aligner and the substrate storage cassettes in the loading position, a carrier tray aligner configured to support and rotate a carrier tray, wherein the carrier tray aligner rotates the carrier tray to position the carrier tray in condition for substrate transferring, and a second robot configured to transfer substrates between the substrate aligner and the carrier tray disposed on the carrier tray aligner.

Another embodiment of the present invention provides a substrate processing system comprising a transfer chamber defining a transfer region, wherein the transfer region maintains a vacuum environment, one or more processing chambers coupled to the transfer chamber, where the one ore more processing chambers are operable to form one or more compound nitride semiconductor layers on a substrate, a load lock chamber coupled to the transfer chamber, wherein the load lock chamber comprises a first slit valve and a second slit valve, and the load lock chamber is connected to the transfer region via the first slit valve, a robot disposed in the transfer region configured to transfer substrate carrier trays among the load lock chamber and the one or more processing chambers, and a loading station connected to the load lock chamber via the second slit valve. The loading station comprises a cassette handling mechanism, wherein the cassette handling mechanism supports one or more substrate storage cassettes and moves each of the one or more substrate storage cassettes into and out of a loading position, a substrate aligner configured to align a substrate, a first robot configured to transfer substrates between the substrate aligner and the substrate storage cassettes in the loading position, a carrier tray aligner configured to support and rotate a substrate carrier tray, wherein the carrier tray aligner rotates the carrier tray to position the substrate carrier tray in condition for substrate transferring, a second robot configured to transfer substrates between the substrate aligner and the substrate carrier tray disposed on the carrier tray aligner, and a third robot configured to transfer a substrate carrier tray between the carrier tray aligner and the load lock chamber.

Yet another embodiment of the present invention provides a method for handling substrates comprising disposing a substrate carrier tray having a plurality of substrate pockets on a carrier aligner and rotating the substrate carrier tray to a transferring position, disposing one or more substrate storage cassettes on a cassette carousel, rotating the cassette carousel to position one substrate storage cassette in a loading position, transferring a substrate from the substrate storage cassette in the loading position to a substrate aligner, aligning the substrate in the substrate aligner, and transferring the substrate in the substrate aligner to the substrate carrier tray on the carrier aligner.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1 is a schematic plan view of a processing system in accordance with one embodiment of the present invention.

FIG. 2 is a schematic top view of an automatic substrate loader in accordance with one embodiment of the present invention.

FIG. 3 is a schematic sectional side view of the automatic substrate loader of FIG. 2.

FIG. 4 is a schematic top view of a substrate carrier disposed in a substrate carrier aligner in accordance with one embodiment of the present invention.

FIG. 5 is a flow chart showing a method for loading a substrate carrier in accordance with one embodiment of the present invention.

FIG. 6 is a flow chart showing a method for unloading a substrate carrier in accordance with one embodiment of the present invention.

To facilitate understanding, identical reference numerals have been used, where possible, to designate identical elements that are common to the figures. It is contemplated that elements disclosed in one embodiment may be beneficially utilized on other embodiments without specific recitation.

### DETAILED DESCRIPTION

Embodiments of the present invention generally relate to the manufacture of semiconductor devices, such as light emitting diodes (LEDs). More particularly, embodiments of the present invention relate to method and apparatus for loading and unloading substrates to a substrate processing system.

The present invention generally provides an apparatus and method for simultaneously processing substrates using a multi-chamber processing system (e.g. a cluster tool) that has an increased system throughput, increased system reliability, and increased substrate to substrate uniformity.

In one embodiment, the multi-chamber processing system is adapted to fabricate compound nitride semiconductor devices in which a substrate is disposed in a HVPE chamber where a first layer is deposited on the substrate and then the substrate is transferred to a MOCVD chamber where a second layer is deposited over the first layer. In one embodiment, the first layer is deposited over the substrate with a thermal chemical-vapor-deposition process using a first group-III element and a nitrogen precursor and the second layer is deposited over the first layer with a thermal chemical-vapor deposition process using a second group-III precursor and a second nitrogen precursor. Although described in connection to a processing system that comprises one MOCVD chamber and one HVPE chamber, alternate embodiments may integrate one or more MOCVD and HVPE chambers.

In one embodiment, the multi-chamber processing system comprises an automatic substrate loader for loading and unloading substrates to and from the multi-chamber processing system. The automatic substrate loader comprises a cassette handling mechanism, a substrate aligner configured to align a substrate, and a carrier tray aligner. The automatic substrate loader further comprises a first robot configured to transfer substrates between the substrate aligner and the substrate storage cassettes, and a second robot configured to transfer substrates between the substrate aligner and the carrier tray disposed on the carrier tray aligner. The automatic substrate loader further comprises a third robot configured to transfer a substrate carrier tray between the automatic substrate loader and a substrate processing system. In one embodiment, the cassette handling mechanism, the substrate aligner and the carrier tray aligner are arranged to enable the first, second, and third robots to have only linear motions therefore simplifies the system.

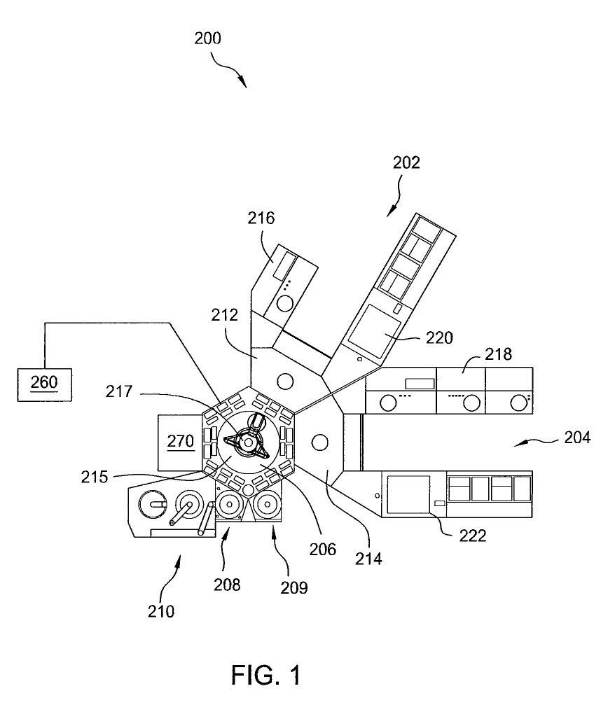

FIG. 1 a schematic plan view of a processing system 200 in accordance with one embodiment of the present invention. The processing system 200 comprises a transfer chamber 206 housing a robot assembly 217, and two or more processing chambers coupled with the transfer chamber 206, such as a MOCVD chamber 202 and a HVPE chamber 204. The processing system 200 further comprises a load lock chamber 208 coupled with the transfer chamber 206, a batch load lock chamber 209 also coupled to the transfer chamber 206. The load lock chamber 208 provides an interface between an outside atmospheric environment and a controlled environment in the transfer chamber 206. The batch load lock chamber 209 is configured for storing substrates. The processing system 200 further comprises a loading station 210 coupled to the load lock chamber 208 and configured for loading substrates to be processed and unloading processed substrate via with the load lock chamber 208. The processing system 200 may further comprise a system controller 260 configured to control and monitor the operation of the entire system.

The transfer chamber 206 may define a transfer region 215. The transfer region 215 may be maintained at a vacuum condition during processing. The transfer chamber 206 comprises a robot assembly 217 disposed in the transfer regions 215 and operable to pick up and transfer substrates between the load lock chamber 208, the batch load lock chamber 209, the MOCVD chamber 202 and the HVPE chamber 204. The movement of the robot assembly 217 may be controlled by a motor drive system, which may include a servo or stepper motor.

Each processing chamber comprises a chamber body (such as element 212 for the MOCVD chamber 202 and element 214 for the HVPE chamber 204) forming a processing region where a substrate is placed to undergo processing, a chemical delivery module (such as element 216 for the MOCVD chamber 202 and element 218 for the HVPE chamber 204) from which gas precursors are delivered to the chamber body, and an electrical module (such as element 220 for the MOCVD chamber 202 and element 222 for the HVPE chamber 204) that includes the electrical system for each processing chamber of the processing system 200. The MOCVD chamber 202 is adapted to perform CVD processes in which metalorganic compounds react with metal hydride compounds to form thin layers of compound nitride semiconductor materials. The HVPE chamber 204 is adapted to perform HVPE processes in which gaseous metal halides are used to epitaxially grow thick layers of compound nitride semiconductor materials on heated substrates. In alternate embodiments, one or more additional chambers 270 may be coupled with the transfer chamber 206. These additional chambers may include, for example, anneal chambers, clean chambers for cleaning carrier plates, or substrate removal chambers. The structure of the processing system permits substrate transfers to occur in a defined ambient environment, including under vacuum, in the presence of a selected gas, under defined temperature conditions, and the like.

The load lock chamber 208 provides an interface between the atmospheric environment of the load station 210 and the controlled environment of the transfer chamber 206. Substrates are transferred between the load lock chamber 208 and the load station 210 via a first slit valve and between the load lock chamber 208 and the transfer chamber 206 via a second slit valve. The load lock chamber 208 comprises a carrier support adapted to support incoming and outgoing carrier trays thereon. In one embodiment, the load lock chamber 208 may comprise multiple carrier supports that are vertically stacked. To facilitate loading and unloading of a carrier tray, the carrier support may be coupled to a stem vertically movable to adjust the height of the carrier support. The load lock chamber 208 is coupled to a pressure control system which pumps down and vents the load lock chamber 208 to facilitate passing the substrate between the vacuum environment of the transfer chamber 206 and the substantially ambient (e.g., atmospheric) environment of the load station 210. In addition, the load lock chamber 208 may also comprise features for temperature control, such as a degas module to heat substrates and remove moisture, or a cooling station for cooling substrates during transfer. Once a carrier tray loaded with substrates has been conditioned in the load lock chamber 208, the carrier plate may be transferred into the MOCVD chamber 202 or the HVPE chamber 204 for processing, or to the batch load lock chamber 209 where multiple carrier plates are stored in standby for processing.

The batch load lock chamber 209 may have a chamber body defining a cavity and a storage cassette moveably disposed within the cavity. The storage cassette comprises a plurality of storage shelves supported by a frame. In one embodiment, the storage shelves are spaced vertically apart and parallel within the storage cassette to define a plurality of storage spaces. Each substrate storage space is adapted to store at least one carrier tray therein supported on a plurality of support pins. The storage shelves above and below each carrier tray establish the upper and lower boundary of the storage space.

During processing, substrates to be processed generally are brought to the loading station 210 in cassettes, which are used to store substrates and transfer substrates among processing systems. Cassettes with substrates to be processed are loaded in the loading station 210, where substrates are extracted from the cassettes and loaded on substrate carrier trays. The carrier trays loaded with substrates are then transferred to the load lock chamber 208. The carrier trays loaded with the substrates are then picked up by the robot assembly 217 within the transfer chamber 206. The substrates in the carrier trays are transferred among the processing chambers 202, 204, and the batch load lock chamber 209 according to the process recipe. When the process is complete, the robot assembly 217 disposed the substrates within the carrier tray back to the load lock chamber 208. The carrier tray loaded with processed substrates is then transferred back to the loading station 210, where the substrates are unloaded from the carrier tray and returned to empty cassettes. The cassettes with processed substrates can then be moved from the loading station 210 for subsequent processing.

Embodiments of the present invention provide a loading station having automatic means to complete substrate transferring between cassettes and carrier trays.

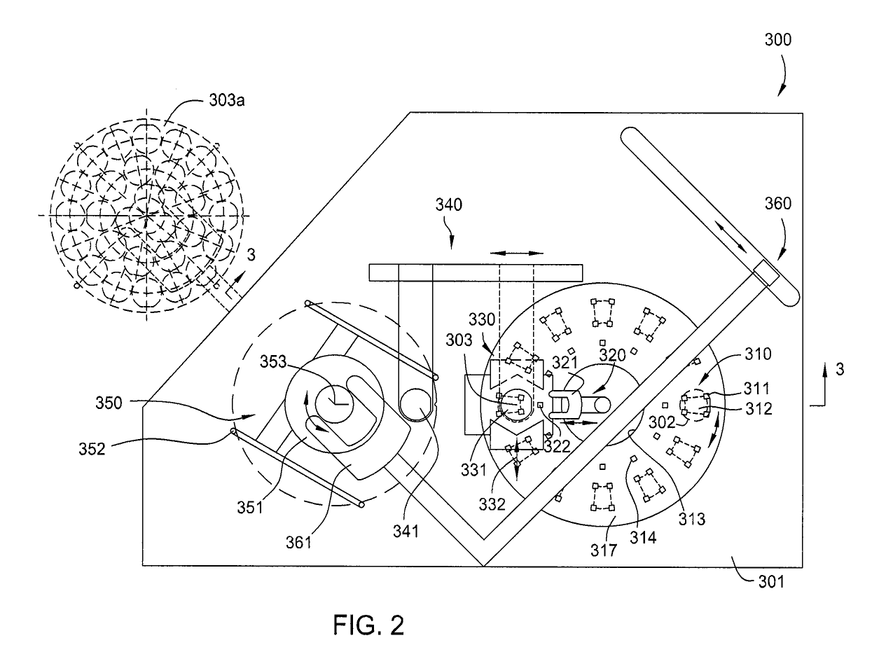

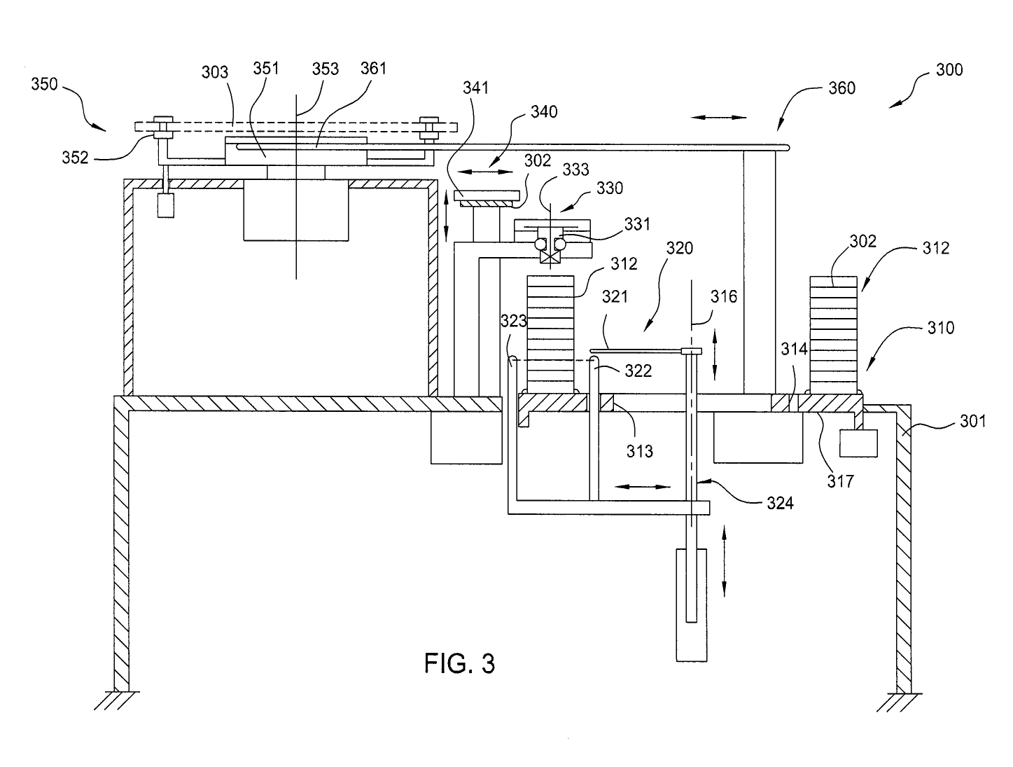

FIG. 2 is a schematic top view of an automatic substrate loader 300 in accordance with one embodiment of the present invention. FIG. 3 is a schematic sectional side view of the automatic substrate loader 300 of FIG. 2. The automatic substrate loader 300 may be used to load and unload substrates to processing systems. The automatic substrate loader 300 may be used to load substrates of various sizes, such as 3, 4, or 6 inch substrates. In one embodiment, the automatic substrate loader 300 is adapted to load and unload substrates having diameter of about 4 inches. In another embodiment, the automatic substrate loader 300 is adapted to load and unload substrates having diameter of about 6 inches. In one embodiment, the automatic substrate loader 300 may be used in place of the loading station 210 of the processing system 200.

The automatic substrate loader 300 comprises a body 301 providing a frame for components. In one embodiment, the automatic substrate loader 300 comprises a cassette carousel 310 configured to secure, support and transfer a plurality of cassettes 312.

The automatic substrate loader 300 further comprises a substrate aligner 330 disposed above the cassette carousel 310, and a cassette interfacing robot 320. The substrate aligner 330 is configured to position a substrate in a certain orientation. The cassette interfacing robot 320 is configured to transfer substrates between the substrate aligner 330 and the cassettes 312 on the cassette carousel 310.

The automatic substrate loader 300 further comprises a carrier tray aligner 350 and a carrier tray loading robot 340. The carrier tray aligner 350 is configured to support and rotate a substrate carrier tray 303 so that a substrate pocket on the substrate carrier tray 303 is in position to be loaded or unloaded by the carrier tray loading robot 340. The carrier tray loading robot 340 is configured to transfer substrate among the substrate aligner 330 and the substrate carrier 303 disposed on the carrier tray aligner 350.

The automatic substrate loader 300 further comprises a carrier tray transferring robot 360 configured to transfer a carrier tray 303 between the carrier tray aligner 330 and a substrate processing system, such as the load lock 208 of the processing system 200.

The cassette carousel 310 may be rotatable about a central axis 316. In one embodiment, the cassette carousel 310 has a plurality of snaps 311 on a supporting surface 317. The snaps 311 are configured to secure a plurality of cassettes 312 on the supporting surface 317. In one embodiment, the plurality of snaps 311 are arranged to along the same radius from the central axis 316 so that the plurality of cassettes 312 are disposed in the same distance from the central axis 316. In one embodiment, the cassette carousel 310 is configured to support and rotate twelve cassettes 312.

The cassette carousel 310 is configured to rotate and position each of cassettes 312 in a loading position near the substrate aligner 330 so that substrates can be transferred between the substrate aligner 330 and the cassette 312 in the loading position. In one embodiment, each cassette 312 may have a plurality of slots, each slot configured to support a substrate 302 thereon. In one embodiment, the substrates 302 may be vertically stacked within the cassettes 312 when the cassettes 312 are disposed on the cassette carousel 310. In one embodiment, a cassette 312 is directly below the substrate aligner 330 when in the loading position. During processing, the cassette 312 may be disposed on or removed from the cassette carousel 310 when the cassettes 312 are in a non-loading position.

In one embodiment, the cassette carousel 310 may have a central opening 313 formed therein. The central opening 313 allows the cassette interfacing robot 320 to be driven by drive mechanism 324 disposed under the cassette carousel 310.

The cassette interfacing robot 320 comprises a robot blade 321 configured to support a substrate in a substantially horizontal orientation. In one embodiment, the robot blade 321 comprises a vacuum chuck configured to secure the substrate during transferring.

In one embodiment, the cassette interfacing robot 320 is configured to move the robot blade 321 horizontally and vertically. The robot blade 321 moves vertically to align with different slots in the cassette 312 in the loading position, to access the substrate aligner 330 disposed vertically above the cassette 312 in the loading position, and to drop off and to pick up a substrate to and from the cassette 312 and the substrate aligner 330. The robot blade 321 moves horizontally to get in and out the cassette 312 and the substrate aligner 330.

In one embodiment, the cassette interfacing robot 320 comprises a sensor assembly moving vertically with the robot blade 321. The sensor assembly is configured to detect the presence of a substrate in the slots of the cassette 312 and to count the number of substrates within the cassette 312. In one embodiment, the sensor assembly is an optical sensor comprising a light emitter 322 and a light receiver 323 disposed on opposite sides of a cassette 312 in the loading position. In one embodiment, the cassette carousel 310 has a plurality of sensor openings 314 located for each set of snaps 311. The sensor openings 314 are configured to allow motions of the sensor assembly.

The substrate aligner 330 is configured to align a substrate and prepare the substrate to be loaded in a substrate carrier. In one embodiment, the substrate aligner 330 may comprise a substrate support 331 configured to rotate a substrate disposed thereon and a centering mechanism 332. The centering mechanism 332 is configured to center the substrate on the substrate support 331. In one embodiment, the centering mechanism 332 may comprise two alignment blocks configured to move symmetrically to a center axis 333 of the substrate support 331.

For substrates with a flat, the substrate aligner 330 may be used to position the flat in a certain direction. The substrate aligner 330 may also position the substrate according to patterns formed on the substrate

The carrier tray aligner 350 is configured to support a substrate carrier tray 303 during loading and unloading, and to position each of a plurality of substrate pockets 372 formed in the carrier tray 303. The carrier tray aligner 350 may comprise a carrier support 351 configured to support the carrier tray 303 and to rotate the carrier tray 303 about a central axis 353 to position a specific substrate pocket in the carrier tray 303. The carrier tray aligner 350 further comprises a centering mechanism 352 configured to center the carrier tray 303 relative to the central axis 353 of the carrier support 351. In one embodiment, the centering mechanism 352 comprises three or more wheels symmetrically movable relative to the central axis 353.

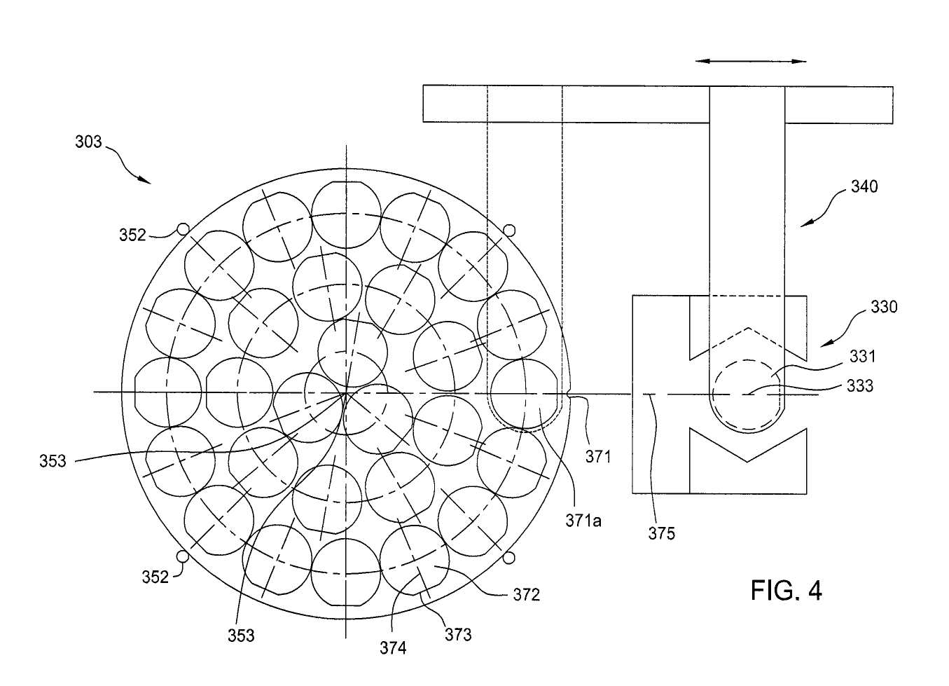

FIG. 4 is a schematic top view of a substrate carrier tray 303 in accordance with one embodiment of the present invention. FIG. 4 schematically illustrates one approach to align substrates during loading.

The substrate carrier tray 303 is disposed in on the carrier tray aligner 350. The carrier tray 303 is substantially circular and having a plurality of substrate pockets 372 formed therein. Each substrate pocket 372 is configured to retain a substrate therein. As shown in FIG. 4, each pocket 372 has a flat 373 for accommodating a substrate with a flat. In one embodiment, the pocket 373 of each pocket 372 is outward from a center of the carrier tray 303 and substantially perpendicular to a radius 374 connecting the center of the carrier tray 303 and the center of the pocket 372. In one embodiment, the carrier tray 303 has a notch 371 as a reference for alignment.

Referring back to FIG. 3, during aligning, a carrier tray 303 is first disposed on the carrier support 351. The carrier tray 303 on the carrier support 351 may be centered by the centering mechanism 352 when the centering wheels simultaneously moving towards the rotating carrier tray 303. The center of the carrier tray 303 substantially coincides with the center axis 353 of the carrier support 351 when the carrier tray 303 is aligned.

Referring to FIG. 4, the carrier support 351 may rotate the carrier tray 303 so that the radius 374 of a pocket 372 aligns with a line 375 connecting the central axis 353 of the carrier support 351 and the central axis 333 of the substrate support 331 to position the pocket 372 in a transferring position. As shown in FIG. 4, pocket 371a is in a transferring position. Each pocket 372 may be positioned in its transferring position similarly.

The substrate 302 disposed on the substrate support 331 has been aligned and the flat on the substrate 302 is substantially parallel to the flat in the pocket 371a in the transferring position. A linear motion from the carrier tray loading robot 340 may transfer the substrate 302 in the substrate support 331 to the pocket 371a, or vise versa.

Referring back to FIG. 2, the carrier tray loading robot 340 is configured to move substrates between the substrate aligner 330 and the carrier aligner 350. In one embodiment, the carrier tray loading robot 340 has two liner motions, a horizontal motion substantially parallel to a line from the center axis 353 of the carrier aligner 350 and the central axis 333 of the substrate aligner 330, and a vertical motion. The vertical motion allows the carrier tray loading robot 340 to pick up and to drop off a substrate, and to accommodation different elevation between the substrate aligner 330 and the carrier aligner 350.

In one embodiment, the carrier tray loading robot 340 may comprise a minimum contact chucking mechanism configured to secure to a substrate on a top surface. In one embodiment, the minimum contact chucking mechanism using the Bernoulli principle to create a low pressure region between the substrate and the robot blade by blowing a vertex flow of air. In one embodiment, a blade 341 of the carrier tray loading robot 340 may contact a substrate within 1 to 2 mm of an edge region.

The carrier tray transferring robot 360 is configured to pick up and transfer a substrate carrier tray 303. In one embodiment, the carrier tray transferring robot 360 may be used to transfer a substrate carrier tray 303 from the carrier aligner 350 to a substrate support position 303a in a load lock chamber, and vise versa. In one embodiment, the carrier tray transferring robot 360 may have a linear horizontal motion and a vertical motion.

The carrier tray transferring robot 360 comprises a robot blade 361 configured to support a substrate carrier tray. In one embodiment, the robot blade 361 may remain under then the substrate carrier tray during loading and unloading.

The automatic substrate loader 300 may be used in atmosphere environment or controlled environment.

It should be noted, other arrangement of the robots 320, 340, 360 and the aligners 330, 350 may be used to accommodate certain space requirement or to maximize usage of the space.

Even though, linear motions of the robots 320, 340, 360 are shown in the automatic substrate loader 300, persons skilled in the art may apply other ranges of motions to complete the loading and unloading process.

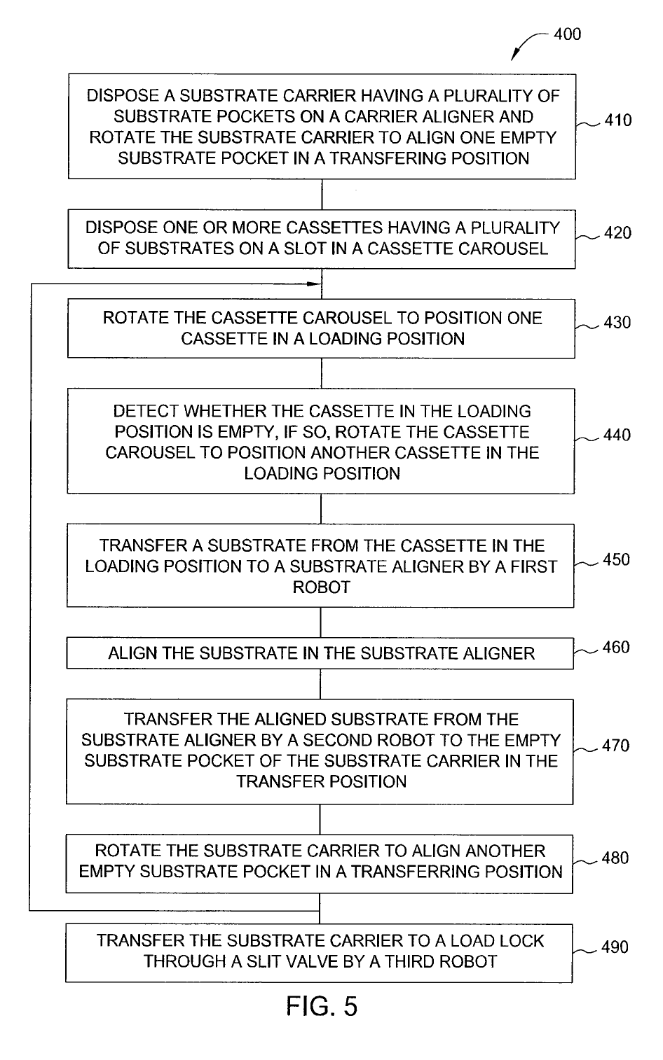

FIG. 5 is a flow chart showing a method 400 for loading a substrate carrier in accordance with one embodiment of the present invention. The method 400 may be performed using an automatic substrate loader, such as the automatic substrate loader 300 described above.

In box 410, a substrate carrier tray, such as the substrate carrier tray 303, having one or more empty pockets is disposed on a carrier aligner, such as the carrier aligner 350. In one embodiment, the substrate carrier tray may be disposed by a carrier transferring robot, such as the carrier transferring robot 360. In another embodiment, the substrate carrier tray may be transferred out of a processing system and after processed substrates are unloaded. The carrier aligner may rotate the substrate carrier tray to position one empty pocket in a transferring position.

In box 420, one or more cassettes, such as cassettes 312, having a plurality of substrates to be processed may be disposed on a cassette carousel, such as the cassette carousel 310.

In box 430, the cassette carousel is rotated to position one cassette in a loading position.

In box 440, detecting the presence of substrates in the cassette in the loading position. Detecting the presence of substrates may be performed by moving an optical sensor, such as sensors 322, 323 relatively to the cassette in the loading position. If no substrate is found in the cassette in the loading position, the cassette carousel may rotate again and position another cassette in the loading position.

In box 450, a substrate is transferred from a slot in the cassette to a substrate aligner, such as the substrate aligner 330. This transferring may be performed by a first robot, such as the cassette interfacing robot 320.

In box 460, the substrate in the substrate aligner may be aligned with the pocket of the carrier tray. In one embodiment, the alignment comprises aligning a flat of the substrate with a flat of the pocket in the transferring position.

In box 470, the aligned substrate in the substrate aligner is transferred to the substrate carrier and dropped in the pocket in the transferring position. In one embodiment, this transferring may be performed by a second robot, such as the carrier tray loading robot 340.

In box 480, the substrate carrier may be rotated to position another empty pocket in its transferring position and operations from boxes 430 to 480 may be repeated until all the pockets are full.

In box 490, when the all the pockets in the substrate carrier are loaded with substrates to be processed, the substrate carrier may be picked up from the carrier aligner and transferred to a processing system, such as the load lock chamber 208 of the processing system 200. In one embodiment, the substrate carrier may be transferred by a third robot, such as the carrier tray transfer robot 360.

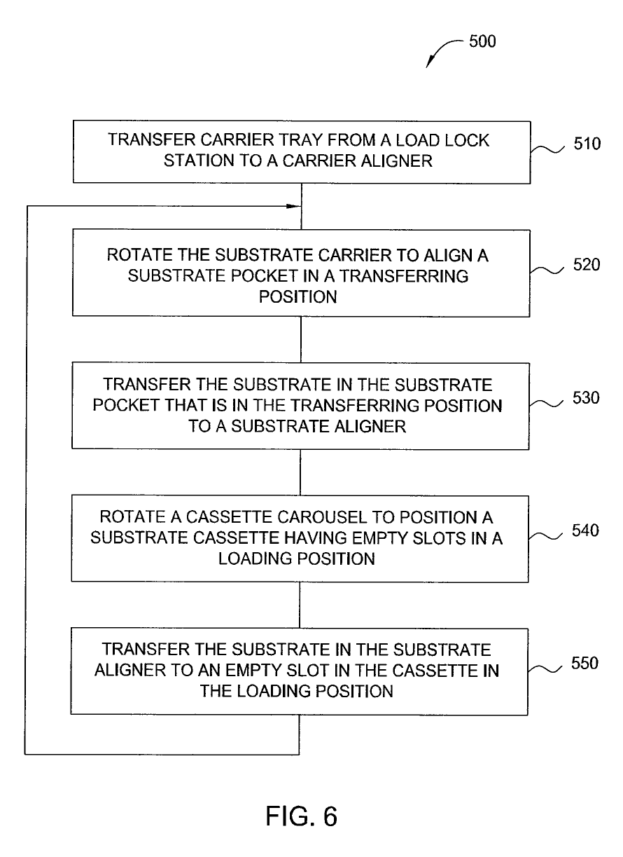

FIG. 6 is a flow chart showing a method 500 for unloading a substrate carrier in accordance with one embodiment of the present invention. The method 500 may be performed using an automatic substrate loader, such as the automatic substrate loader 300 described above.

In box 510, a substrate carrier tray having a plurality of substrates may be transferred to a carrier aligner, such as the carrier aligner 350. The substrate carrier tray may be transferred by a carrier tray transferring robot, such as the robot 360, from a processing system, such as the processing system 200.

In box 520, the substrate carrier tray is rotated and a substrate pocket having a substrate therein is positioned in a transferring position.

In box 530, the substrate in the transferring position may be picked up from the substrate carrier tray and transferred to a substrate support, such as the substrate support 331 of the substrate aligner 330. This transferring may be performed by a substrate transferring robot, such as the robot 340.

In box 540, a cassette carousel is rotated to position a cassette having one or more empty slots in a loading position.

In box 550, the substrate in the substrate support is picked up and transferred to an empty slot in the cassette in the loading station. This transferring may be performed by a cassette interfacing robot, such as the robot 320.

Operations in boxes 520, 530, 540, and 550 may be repeated until the substrate carrier tray is empty. Filled cassettes may be removed from the cassette carrousel when the cassette is not in the loading position.

While the foregoing is directed to embodiments of the present invention, other and further embodiments of the invention may be devised without departing from the basic scope thereof, and the scope thereof is determined by the claims that follow.

1. A substrate loading station, comprising:
a cassette handling mechanism, wherein the cassette handling mechanism supports one or more substrate storage cassettes and moves each of the one or more substrate storage cassettes into and out of a loading position;
a substrate aligner configured to align a substrate;
a first robot configured to transfer substrates between the substrate aligner and the substrate storage cassettes in the loading position;
a carrier tray aligner configured to support and rotate a carrier tray, wherein the carrier tray aligner rotates the carrier tray to position the carrier tray in condition for substrate transferring; and
a second robot configured to transfer substrates between the substrate aligner and the carrier tray disposed on the carrier tray aligner.

2. The substrate loading station of claim 1, wherein the cassette handling mechanism comprises a cassette carrousel rotatable about a central axis of the cassette carousel, and the cassette carousel has a plurality of cassette holding positions disposed at the same radius from the central axis.

3. The substrate loading station of claim 2, wherein each cassette holding position has a set of snaps configured to hold a substrate storage cassette in a vertical position so that a plurality of substrates may be vertically stacked in the substrate storage cassette.

4. The substrate loading station of claim 3, wherein the loading position of a substrate storage cassette is vertically aligned with the substrate aligner, and the first robot transfers substrates between the substrate aligner and the substrate storage cassette in the loading position via linear vertical motion.

5. The substrate loading station of claim 3, further comprising a sensor assembly, wherein the sensor assembly detects presence of any substrates in the substrate storage cassette in the loading position.

6. The substrate loading station of claim 5, wherein the sensor assembly comprises a light emitter and a light receiver disposed on opposite sides of the substrate storage cassette in the loading position.

7. The substrate loading station of claim 5, wherein the sensor assembly is attached to the first robot, and the sensor assembly detects presence of any substrates in the substrate storage cassette in the loading position when the first robot moves relative to the substrate storage cassette in the loading position.

8. The substrate loading station of claim 2, wherein the cassette carousel is a circular disk having a central opening, and the first robot is disposed within the central opening.

9. The substrate loading station of claim 1, wherein the carrier tray has a plurality of pockets, each pocket is configured to retain a substrate therein, and the carrier tray aligner rotates the carrier tray disposed thereon to position each pocket within the path of the second robot.

10. The substrate loading station of claim 9, further comprises a third robot configured to transfer the substrate carrier tray to and from the carrier tray aligner.

11. A substrate processing system, comprising:
a transfer chamber defining a transfer region, wherein the transfer region maintains a vacuum environment;
one or more processing chambers coupled to the transfer chamber, where the one ore more processing chambers are operable to form one or more compound nitride semiconductor layers on a substrate;
a load lock chamber coupled to the transfer chamber, wherein the load lock chamber comprises a first slit valve and a second slit valve, and the load lock chamber is connected to the transfer region via the first slit valve;
a robot disposed in the transfer region configured to transfer substrate carrier trays among the load lock chamber and the one or more processing chambers; and
a loading station connected to the load lock chamber via the second slit valve, wherein the loading station comprises:
a cassette handling mechanism, wherein the cassette handling mechanism supports one or more substrate storage cassettes and moves each of the one or more substrate storage cassettes into and out of a loading position;
a substrate aligner configured to align a substrate;
a first robot configured to transfer substrates between the substrate aligner and the substrate storage cassettes in the loading position;
a carrier tray aligner configured to support and rotate a substrate carrier tray, wherein the carrier tray aligner rotates the carrier tray to position the substrate carrier tray in condition for substrate transferring;
a second robot configured to transfer substrates between the substrate aligner and the substrate carrier tray disposed on the carrier tray aligner; and
a third robot configured to transfer a substrate carrier tray between the carrier tray aligner and the load lock chamber.

12. The substrate processing system of claim 11, wherein the cassette handling mechanism comprises a cassette carrousel rotatable about a central axis of the cassette carousel, and the cassette carousel has a plurality of cassette holding positions disposed at the same radius from the central axis.

13. The substrate processing system of claim 12, wherein each cassette holding position has a set of snaps configured to hold a substrate storage cassette in a vertical position so that a plurality of substrates may be vertically stacked in the substrate storage cassette.

14. The substrate processing system of claim 13, wherein the loading stations further comprises a sensor assembly, wherein the sensor assembly detects presence of any substrates in the substrate storage cassette in the loading position.

15. The substrate processing system of claim 12, wherein the cassette carousel is a circular disk having a central opening, and the first robot is disposed within the central opening.

16. The substrate processing system of claim 11, wherein the carrier tray has a plurality of pockets, each pocket is configured to retain a substrate therein, and the carrier tray aligner rotates the carrier tray disposed thereon to position each pocket within the path of the second robot

17. A method for handling substrates, comprising:
disposing a substrate carrier tray having a plurality of substrate pockets on a carrier aligner and rotating the substrate carrier tray to a transferring position;
disposing one or more substrate storage cassettes on a cassette carousel;
rotating the cassette carousel to position one substrate storage cassette in a loading position;
transferring a substrate from the substrate storage cassette in the loading position to a substrate aligner;
aligning the substrate in the substrate aligner; and
transferring the substrate in the substrate aligner to the substrate carrier tray on the carrier aligner.

18. The method of claim 17, wherein transferring the substrate from the substrate storage cassette to the substrate aligner is performed by a first robot, and transferring the substrate in the substrate aligner to the substrate carrier tray is performed by a second robot.

19. The method of claim 18, wherein rotating the substrate carrier tray to a transferring position comprising rotating the substrate carrier tray to position a first substrate pocket in the path of the second robot.

20. The method of claim 19, further comprising rotating the substrate carrier tray to position a second substrate pocket in the path of the second robot, and repeating transferring a substrate from the substrate storage cassette to the substrate aligner, aligning the substrate, and transferring the substrate from the substrate aligner to the substrate carrier tray.

21. The method of claim 17, further comprising detecting the presence of the substrate in the substrate storage cassette in the loading station prior to transferring the substrate from the substrate storage cassette to the substrate aligner.

22. The method of claim 17, further comprising transferring the substrate carrier tray from the carrier tray aligner to a processing system using a third robot.
